(19) United States
(12) Patent Application Publication
(10) Pub. No.: US 2025/0105810 A1
(43) Pub. Date: Mar. 27, 2025

(54) DIFFERENTIAL AMPLIFIER INCLUDING FEEDBACK LOOP CIRCUITS, ELECTRONIC DEVICE, AND OPERATING METHOD THEREOF

(71) Applicant: SAMSUNG ELECTRONICS CO., LTD., SUWON-SI (KR)

(72) Inventors: Kibaek Kwon, Suwon-si (KR); Byoungjoo Yoo, Suwon-si (KR); Youngho Choi, Suwon-si (KR)

(21) Appl. No.: 18/825,204

(22) Filed: Sep. 5, 2024

(30) Foreign Application Priority Data
Sep. 27, 2023 (KR) 10-2023-0131176
Nov. 28, 2023 (KR) 10-2023-0168235

(51) Int. Cl. H03F 3/45; H03F 1/02

(52) U.S. Cl. CPC H03F 3/45677; H03F 1/0205; H03F 2200/481; H03F 2203/45334

(57) ABSTRACT

Provided are a differential amplifier forming a first feedback loop and a second feedback loop by including feedback loop circuits, an electronic device, and an operating method thereof. The differential amplifier configured to generate at least one pair of differential output signals by amplifying at least one pair of differential input signals and to generate an output common-mode signal based on the at least one pair of differential output signals. The main amplifier includes a first current mirror that generates first currents. A first feedback loop circuit is connected to an output node of the main amplifier which outputs the output common-mode signal, and forms a first feedback loop that feeds back the output common-mode signal. A second feedback loop circuit generates a control signal that controls the first currents based on the output common-mode signal, and forms a second feedback loop.

### CROSS-REFERENCE TO RELATED APPLICATIONS

This application is based on and claims priority under 35 U.S.C. § 119 to Korean Patent Application No. 10-2023-0131176, filed on Sep. 27, 2023, and 10-2023-0168235, filed on Nov. 28, 2023, in the Korean Intellectual Property Office, the disclosures of which are incorporated by reference herein in their entireties.

### TECHNICAL FIELD

This disclosure relates to a differential amplifier, an electronic device including the same, and an operating method thereof.

### DISCUSSION OF RELATED ART

When using an analog amplifier to amplify signals, a bias signal should be stably set for transistors to operate in a saturated state. Amongst analog amplifiers, a fully differential amplifier (FDA) may refer to a high gain voltage amplifier having a differential input and a differential output.

FDAs may require a common-mode feedback (CMFB) operation in order to stably operate, but a related art CMFB operation may have insufficient stability or cause high current consumption due to high impedance at the output terminal of an FDA. Therefore, research is ongoing to develop differential amplifier circuits for decreasing current consumption of FDAs while ensuring their stability.

### SUMMARY

Embodiments of the inventive concept provide a differential amplifier increasing phase margin and decreasing current consumption by forming a first feedback loop and a second feedback loop, an electronic device, and an operating method thereof.

According to an aspect of the inventive concept, there is provided a differential amplifier circuit including a main amplifier circuit configured to generate at least one pair of differential output signals by amplifying at least one pair of differential input signals and generate an output common-mode signal based on the at least one pair of differential output signals. The main amplifier includes a first current mirror that generates first currents. A first feedback loop circuit is connected to an output node of the main amplifier outputting the output common-mode signal, and forms a first feedback loop that feeds back the output common-mode signal. A second feedback loop circuit is configured to generate a control signal controlling the first currents based on the output common-mode signal and form a second feedback loop.

According to another aspect of the inventive concept, there is provided an electronic device including a main amplifier configured to generate at least one pair of differential output signals by amplifying at least one pair of differential input signals. The main amplifier includes a first current mirror including a plurality of transistors, and a common-mode signal sensor configured to generate an output common-mode signal based on the at least one pair of differential output signals. A first feedback loop circuit is connected to an output node of the common-mode signal sensor which outputs the output common-mode signal and is configured to provide a feedback loop for the output common-mode signal. A second feedback loop circuit is configured to generate a control signal controlling the first current mirror circuit based on the output common-mode signal and provide the control signal to gate terminals of the plurality of transistors.

According to another aspect of the inventive concept, there is provided an operating method of a differential amplifier circuit, the method including receiving at least one pair of differential input signals through input transistors connected to terminals of one or more current mirrors, generating an output common-mode signal based on the at least one pair of differential input signals, controlling impedance of an output node at which the output common-mode signal is provided, based on the output common-mode signal and a target signal through a first feedback loop, generating a control signal based on the output common-mode signal and the target signal through a second feedback loop, and controlling the one or more current mirrors based on the control signal.

### BRIEF DESCRIPTION OF THE DRAWINGS

Embodiments will be more clearly understood from the following detailed description taken in conjunction with the accompanying drawings in which:

FIG. 1 is a block diagram illustrating a differential amplifier circuit according to an embodiment;

FIG. 2 is a schematic diagram illustrating a first feedback loop circuit according to an embodiment;

FIG. 3 is a schematic diagram illustrating a second feedback loop circuit according to an embodiment;

FIG. 4 is a schematic/block diagram illustrating a differential amplifier circuit according to an embodiment;

FIG. 5 is a schematic/block diagram illustrating a differential amplifier circuit according to a comparative embodiment;

FIG. 6 depicts graphs illustrating currents consumed by a differential amplifier circuit according to a comparative embodiment and a differential amplifier circuit according to an embodiment;

FIG. 7 is a schematic/block diagram illustrating a differential amplifier circuit according to an embodiment;

FIG. 8 is a schematic/block diagram illustrating a differential amplifier circuit according to an embodiment;

FIG. 9 is a flowchart illustrating an operating method of a differential amplifier circuit according to an embodiment;

FIG. 10 is a flowchart illustrating an operating method of a differential amplifier circuit according to an embodiment;

FIG. 11 is a block diagram illustrating a differential amplifier circuit according to an embodiment;

FIG. 12 is a block diagram illustrating an electronic device according to an embodiment; and

FIG. 13 is a block diagram illustrating communication apparatuses including a communication device according to an embodiment.

### DETAILED DESCRIPTION OF EMBODIMENTS

Hereinafter, embodiments will be described in detail with reference to the accompanying drawings.

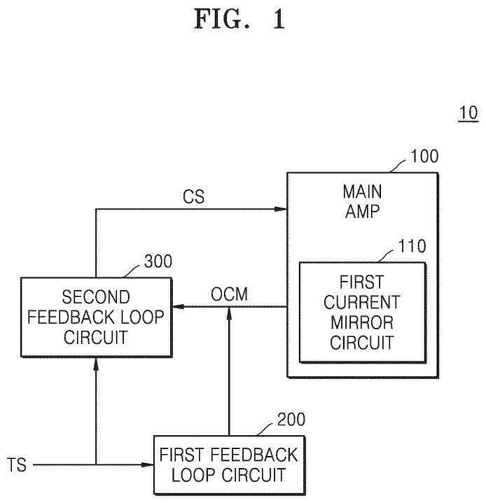

FIG. 1 is a block diagram illustrating a differential amplifier circuit (“differential amplifier”) 10, according to an embodiment. The differential amplifier 10 may include an analog amplifier for amplifying signals. For example, the differential amplifier 10 may be a fully differential amplifier (FDA), which is a high gain voltage amplifier having a differential input and a differential output.

The differential amplifier circuit 10 may include a main amplifier circuit (“main amplifier”) 100, a first feedback loop circuit 200, and a second feedback loop circuit 300.

The main amplifier 100 may receive at least one pair of differential input signals and generate at least one pair of differential output signals by amplifying the at least one pair of differential input signals. In some embodiments, to compensate for a reduction in signal magnitude due to channel loss and various noise components, the main amplifier 100 may generate the at least one pair of differential output signals by amplifying the at least one pair of differential input signals. For example, the at least one pair of differential input signals may be clock input signals having voltage levels complementary to each other, and the at least one pair of differential output signals may be clock signals having voltage levels complementary to each other. The pair of differential input signals may be any type of signals.

The main amplifier 100 may generate an output common-mode signal OCM based on the at least one pair of differential output signals. Here, a common-mode signal may be defined as a signal having an average voltage between a pair of differential signals. Thus, the common-mode signal may indicate a representative value of signals. For example, an input common-mode signal of a pair of differential input signals may be defined as a signal having an average voltage between the two input signals. Similarly, the output common-mode signal OCM of a pair of differential output signals may be defined as a signal having an average voltage between the pair of differential output signals.

The main amplifier 100 may include a first current mirror circuit (“current mirror”) 110. The first current mirror 110 may be a circuit generating a current in a second path that is a copy (mirror) of a current in a first path. For example, the first current mirror 110 may include a plurality of transistors and may output constant current by controlling the plurality of transistors.

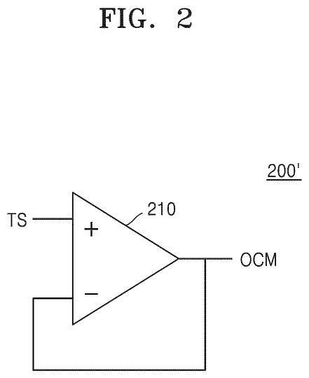

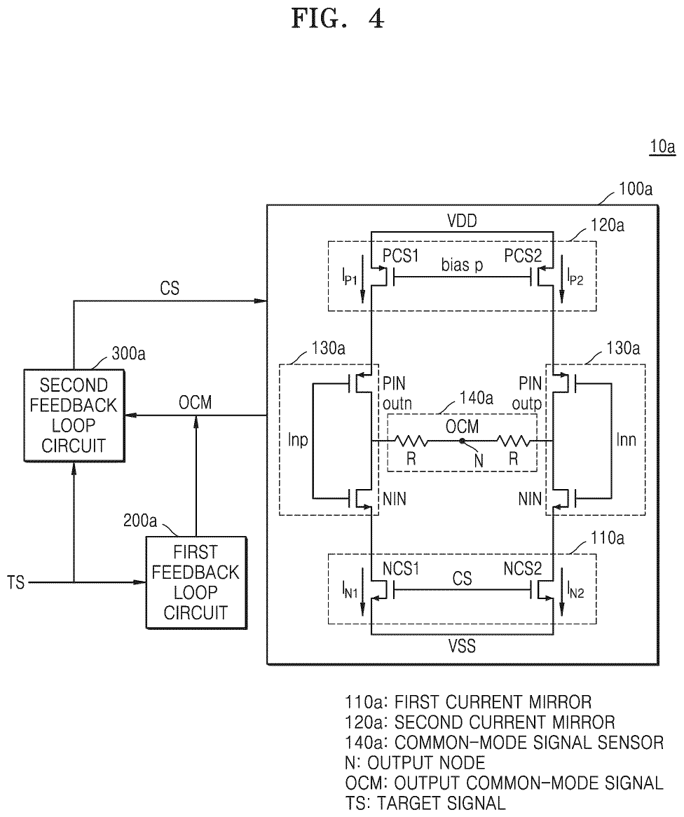

The first feedback loop circuit 200 may be connected to an output node “N” (see, e.g., FIG. 4) within the main amplifier 100, where the output node N outputs the output common-mode signal OCM. The first feedback loop circuit 200 may form a first feedback loop that feeds back the output common-mode signal OCM to an input of the first feedback loop circuit (see, e.g., FIG. 2). The first feedback loop may be a path starting from and returning back to the output node via the first feedback loop circuit 200.

In some embodiments, the first feedback loop circuit 200 may include a buffer circuit having an output terminal and a plurality of input terminals, one of which is connected to the output terminal. The buffer circuit may be a circuit with a relatively high input impedance and a relatively low output impedance.

For example, the first feedback loop circuit 200 may have two input terminals. One input terminal may receive a target signal TS as an input signal and the other input terminal may be connected to the output terminal. The output terminal may be connected to the output node, which is within the main amplifier 100 and outputs the output common-mode signal OCM. The target signal TS may refer to a predetermined signal for adjusting the output common-mode signal OCM.

The first feedback loop 200 has a relatively low output impedance and is connected to the output node, which is within the main amplifier 100 and outputs the output common-mode signal OCM, and thus may decrease impedance of the output node. When the impedance of the output node decreases, phase margin of the differential amplifier 10 may increase. Phase margin may refer to a difference of as much as −180° from phase delay for an output signal relative to an input signal of an amplifier at unity gain (e.g., 0 dB gain).

For example, when the phase delay is −135°, the phase margin may be −135°−(−180°)=45°. As the phase margin of the differential amplifier 10 increases, the stability of the differential amplifier 10 may further improve. The stability of the differential amplifier 10 may refer to an extent to which an output of the differential amplifier 10 maintains a constant state without oscillating. By including the first feedback loop, the stability of the differential amplifier 10 may improve.

The second feedback loop circuit 300 may form a second feedback loop by generating a control signal CS based on the output common-mode signal OCM. The second feedback loop may refer to a path from the output node via the second feedback loop 300 to a node, which is within the main amplifier 100 and receives the control signal CS. The control signal CS may be or include a signal controlling the first current mirror 110 to adjust the magnitude of current generated by the first current mirror 110.

the second feedback loop circuit 300 may receive the output common-mode signal OCM and the target signal TS as input signals and may compare the output common-mode signal OCM with the target signal TS and generate the control signal CS based on the comparison.

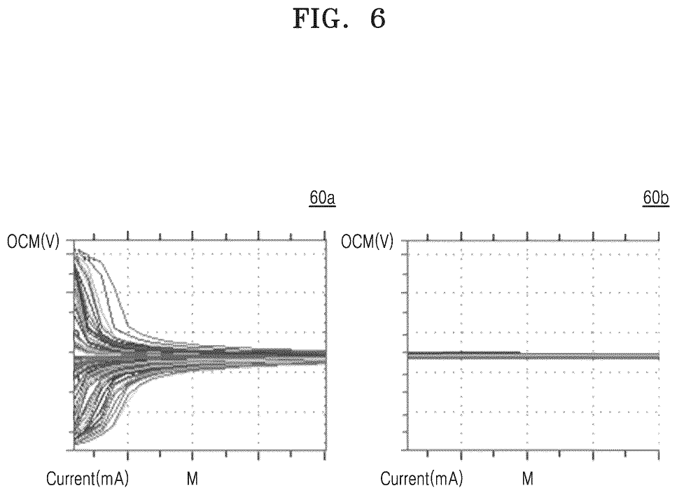

The second feedback loop circuit 300 may control the magnitude of current generated by the first current mirror 110 based on the control signal CS, so that current consumed in the first feedback loop circuit 200 may decrease. An example of such current reduction is described below with reference to FIG. 6.

Accordingly, the differential amplifier 10 may include two feedback loops and thus may exhibit improved stability and reduced current consumption. The improvement in stability may be the result of decreased impedance of the output node of the main amplifier 100 and increased phase margin of the differential amplifier 10. The differential amplifier 10 may form the second feedback loop through the second feedback loop circuit 300, and may thus control the current generated by the first current mirror 110 and decrease the current consumed in the first feedback loop circuit 200.

FIG. 2 is a schematic diagram illustrating a first feedback loop circuit according to an embodiment. A first feedback loop circuit 200′ may be an example of the first feedback loop circuit 200 of FIG. 1 forming the first feedback loop, so that redundant descriptions as those of FIG. 1 are omitted.

Referring to FIGS. 1 and 2, the first feedback loop circuit 200′ may form a first feedback loop. The first feedback loop circuit 200′ may include an operational amplifier (OP-AMP) 210 including a first input terminal (e.g., a positive input terminal “+”), a second input terminal (e.g., a negative input terminal “−”), and an output terminal (at which the signal OCM is output). Thus, the output common-mode signal OCM may be fed back to the negative input terminal of the OP-AMP 210 in the first feedback loop. The first input terminal may receive a target signal TS as an input, and the second input terminal may be connected to the output terminal. The target signal TS may be a predetermined signal for controlling the output common-mode signal OCM. The output terminal may be connected to the output node N within the main amplifier 100 outputting the output common-mode signal OCM. The first feedback loop may be a path starting from and returning back to the output terminal via the second input terminal.

Since the second input terminal of the first feedback loop circuit 200′ is connected to the output terminal, the first feedback loop circuit 200′ may function as a buffer circuit with a relatively high input impedance and a relatively low output impedance. Accordingly, the first feedback loop circuit 200′ may decrease impedance of the output node connected to the output terminal and increase phase margin of the differential amplifier 10. Since stability increases as phase margin increases, the differential amplifier 10 may increase the stability of the differential amplifier 10 due to the first feedback loop.

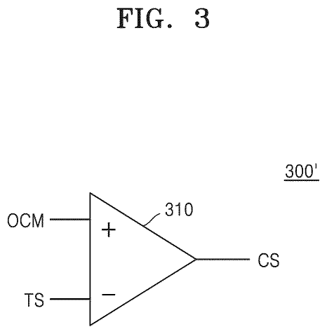

FIG. 3 is a schematic/block diagram illustrating a second feedback loop according to an embodiment. A second feedback loop circuit 300′ may be an example of the second feedback loop circuit 300 of FIG. 1, and redundant descriptions as those of FIG. 1 are omitted.

Referring to FIGS. 1 and 3, the second feedback loop circuit 300′ may form a second feedback loop. The second feedback loop circuit 300′ may include an OP-AMP 310 including a first input terminal (e.g., a positive input terminal “+”), a second input terminal (e.g., a negative input terminal “−”), and an output terminal, and the OP-AMP may have a gain greater than 1. The first input terminal may be connected to the output node N within the main amplifier 100 (outputting the output common-mode signal OCM), and the second input terminal may receive a target signal TS as an input. The second feedback loop circuit 300′ may compare the output common-mode signal OCM with the target signal TS which have been received through the first input terminal and the second terminal, may generate a control signal CS based on the comparison, and may output the control signal CS to the output terminal. The second feedback loop may be a path starting from and returning back to the output node N of the main amplifier 100 via the second feedback loop circuit 300′ and a node, which is within the first current mirror 110 and receives the control signal CS. In some embodiments, the OP-AMP 310 has a gain of 1.

The control signal CS may control the first current mirror 110 to adjust the magnitude of current generated by the first current mirror 110. The second feedback loop circuit 300′ may control the magnitude of current generated by the first current mirror 110 based on the control signal CS, so that current consumed in the first feedback loop circuit 200 may decrease.

FIG. 4 is a schematic/block diagram illustrating a differential amplifier according to an embodiment. A differential amplifier 10a may be an example of the differential amplifier 10 of FIG. 1. A first feedback loop circuit 200a and a second feedback loop circuit 300a may be identical to the first feedback loop circuit 200 and the second feedback loop circuit 300, respectively, of FIG. 1, so that redundant descriptions as those of FIG. 1 are omitted.

Referring to FIG. 4, a main amplifier 100a may include a first current mirror 110a, a second current mirror 120a, input transistors 130a, and a common-mode signal sensor 140a.

The first current mirror 110a may generate first currents IN₁ and IN₂ and allow current flowing through the input transistors 130a to flow to a reference voltage terminal VSS. (Alternatively, “VSS” may be considered a reference voltage such as ground or a negative voltage).

The first current mirror 110a may include a plurality of transistors NCS1 and NCS2, and first terminals (e.g., a drain terminal) of each of the plurality of transistors NCS1 and NCS2 may be connected to the input transistors 130a. The first terminals (e.g., a source terminal) of each of the plurality of transistors NCS1 and NCS2 may be connected to the voltage terminal VSS.

A gate terminal of the transistor NCS1 may be connected to a gate terminal of the transistor NCS2. The gate terminals of the plurality of transistors NCS1 and NCS2 may receive the control signal CS from the second feedback loop circuit 300a. The control signal CS may be a voltage capable of controlling the plurality of transistors NCS1 and NCS2 such that magnitudes of the first currents I_{N1} and I_{N2} are the same as magnitudes of second currents I_{P1} and I_{P2}. Since the first current I_{N2} may be copied from the first current I_{N1} with the same magnitude, the first current mirror 110a may generate each of the first currents I_{N1} and I_{N2} having the same magnitude as each of the second currents I_{P1} and I_{P2}. The first current mirror 110a may allow the generated first currents I_{N1} and I_{N2} to flow to the voltage terminal VSS.

The second feedback loop circuit 300a may control the first current mirror circuit 110a to generate the first currents I_{N1} and I_{N2} having the same magnitude as the second currents I_{P1} and I_{P2}. When the magnitudes of the first currents I_{N1} and I_{N2} are the same as the magnitudes of the second currents I_{P1} and I_{P2}, there is no difference between the first currents I_{N1} and I_{N2} and the second currents I_{P1} and I_{P2}. As a result, the first feedback loop circuit 200a may not need to further consume current by as much as the current difference (that otherwise would exist), thereby reducing current consumed in the first feedback loop circuit 200a. An example of current reduction is described below with reference to FIG. 6.

The second current mirror 120a may generate the second currents I_{P1} and I_{P2} and supply the second currents I_{P1} and I_{P2} to the input transistors 130a. The second current mirror 120a may include a plurality of transistors PCS1 and PCS2, and first terminals (e.g., a source terminal) of the plurality of transistors PCS1 and PCS2 may be connected to a voltage terminal VDD. (Explained differently, VDD is a supply voltage applied to the transistors PCS1 and PCS2.) Voltage of the voltage terminal VDD may be higher than voltage of the voltage terminal VSS. Second terminals (e.g., a drain terminal) of the plurality of transistors PCS1 and PCS2 may be connected to the input transistors 130a.

A gate terminal of the transistor PCS1 may be connected to a gate terminal of the transistor PCS2. The gate terminals of the plurality of transistors PCS1 and PCS2 may receive a bias voltage bias_p. The bias voltage bias_p may be a control voltage at which the plurality of transistors PCS1 and PCS2 may operate. Since the second current I_{P2} may be copied from the second current I_{P1} with the same magnitude based on the bias voltage bias_p, the second current mirror 120a may generate the second currents I_{P1} and I_{P2} having the same magnitude. The second current mirror 120a may supply the generated second currents I_{P1} and I_{P2} to the input transistors 130a.

The input transistors 130a may receive at least one pair of differential input signals Inp and Inn and generate at least one pair of differential output signals outn and outp by amplifying the at least one pair of differential input signals. In some embodiments, the input transistors 130a may be P-type transistors PIN and N-type transistors NIN and may be arranged to form two inverters. Each of the inverters may include one P-type transistor PIN and one N-type transistor NIN and may be a circuit receiving an input signal and outputting an output signal by inverting the input signal.

The common-mode signal sensor 140a may include the output node N at which the output common-mode signal OCM is output, where the signal OCM is based on the at least one pair of differential output signals outn and outp. The common-mode signal sensor 140a may include two resistors R and the output node N may be located between the two resistors R. The two resistors R may divide the at least one pair of differential output signals outn and outp to generate the output common-mode signal OCM.

Impedance of the gate terminals of the plurality of transistors PCS1, PCS2, NCS1, and NCS2 may be relatively high and, when impedance of the output node N is also relatively high, phase margin of the differential amplifier 10a may decrease. (Here, “impedance of the output node” may be understood as output impedance (impedance “looking back” into the circuit) at the circuit point of the node N.) The first feedback loop 200a may be connected to the output node N and decrease the impedance of the output node N. Accordingly, the impedance of the output node N may be relatively lower than the impedance of the gate terminals of the plurality of transistors PCS1, PCS2, NCS1, and NCS2, thus increasing the phase margin of the differential amplifier 10. The differential amplifier 10a may improve stability of the differential amplifier 10a by forming the first feedback loop.

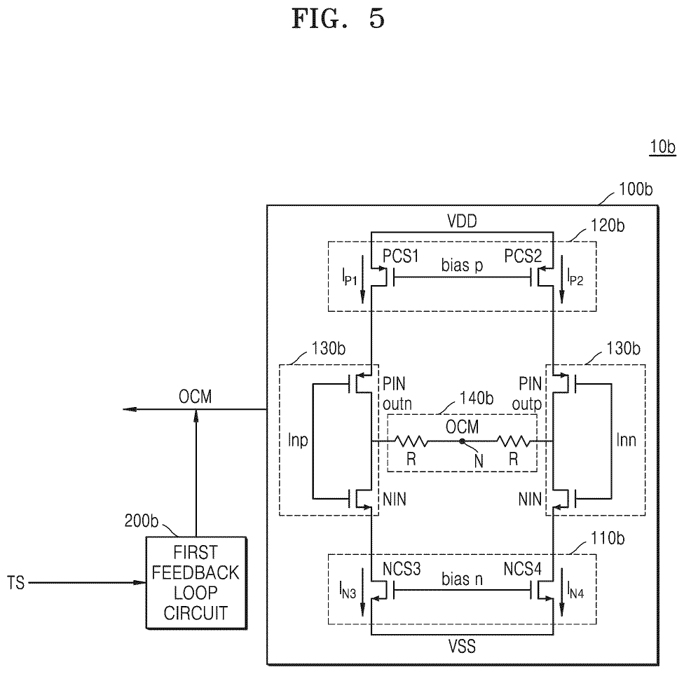

FIG. 5 is a schematic/block diagram illustrating a differential amplifier according to a comparative embodiment. FIG. 6 depicts graphs illustrating currents consumed by a differential amplifier according to a comparative embodiment and a differential amplifier according to an embodiment.

Referring to FIG. 5, a differential amplifier 10b according to a comparative embodiment may include a main amplifier 100b and a first feedback loop circuit 200b. The first feedback loop circuit 200b may be identical to the first feedback loop circuit 200a of FIG. 4.

The main amplifier 100b may include a first current mirror 110b, a second current mirror 120b, input transistors 130b, and a common-mode signal sensor 140b. The second current mirror 120b, the input transistors 130b, and the common-mode signal sensor 140b may be respectively identical to the second current mirror 120a, the input transistors 130a, and the common-mode signal sensor 140a of FIG. 4.

Unlike the differential amplifier 10a of FIG. 4, the differential amplifier 10b does not include the second feedback loop circuit 300a, and thus the first current mirror 110b may receive a bias voltage bias_n through gate terminals of a plurality of transistors NCS3 and NCS4. The bias voltage bias_n may refer to a control voltage at which the plurality of transistors NCS3 and NCS4 may operate. Since a third current I_{N4} may be copied from a third current I_{N3} with the same magnitude based on the bias voltage bias_n, the first current mirror 120b may generate the third currents I_{P3} and I_{P4} having the same magnitude.

However, unlike the differential amplifier 10a of FIG. 4, the differential amplifier 10b does not include the second feedback loop circuit 300a, and thus the bias voltage bias_n may not be adjusted. Accordingly, the third currents I_{N3} and I_{N4} may have values different from the second currents I_{P1} and I_{P2}.

Referring further to FIG. 6, a first graph 60a is a graph illustrating an example output common-mode signal OCM and current consumed in the first feedback loop circuit 200b of the differential amplifier 10b, and a second graph 60b is a graph illustrating an example of the output common-mode signal OCM and current consumed in the first feedback loop circuit 200a of the differential amplifier 10a of FIG. 4.

The horizontal axis of the first graph 60a indicates the current consumed in the first feedback loop circuit 200b of the differential amplifier 10b and the vertical axis indicates the output common-mode signal OCM of the differential amplifier 10b. The horizontal axis of the second graph 60b indicates the current consumed in the first feedback loop circuit 200a of the differential amplifier 10a of FIG. 4 and the vertical axis indicates the output common-mode signal OCM of the differential amplifier 10a of FIG. 4.

Referring to the first graph 60a, when the first feedback loop circuit 200b consumes a current of M (mA) (e.g., 2 mA) or more, it may be seen that the output common-mode signal OCM of the differential amplifier 10b has a constant value, and when the first feedback loop circuit 200b consumes a current of less than M (mA), it may be seen that the output common-mode signal OCM of the differential amplifier 10b does not have a constant value.

On the other hand, referring to the second graph 60b, when the first feedback loop circuit 200a consumes a current of M (mA) or more, and even when the first feedback loop circuit 200a consumes a current of M (mA) or less, it may be seen that the output common-mode signal OCM of the differential amplifier 10a of FIG. 4 has a constant value.

The differential amplifier 10a of FIG. 4 may include the second feedback loop 300a forming a second feedback loop and control the first current mirror 110a of FIG. 4 to generate the first currents I_{N1} and I_{N2} having the same magnitude as the second currents I_{P1} and I_{P2}. When the magnitudes of the second currents I_{P1} and I_{P2} are different from the magnitudes of the first currents I_{N1} and I_{N2}, the first feedback loop circuit 200a may need to consume more current by as much as the difference between different current magnitudes, as compared to the case where the magnitudes of the second currents I_{P1} and I_{P2} are the same as the magnitudes of the first currents I_{N1} and I_{N2}.

Accordingly, the differential amplifier 10b according to the comparative embodiment may need to consume a current of M (mA) or more, whereas the differential amplifier 10a according to the embodiment may maintain the output common-mode signal OCM constant despite a relatively low current consumption (e.g., a current of less than M (mA)).

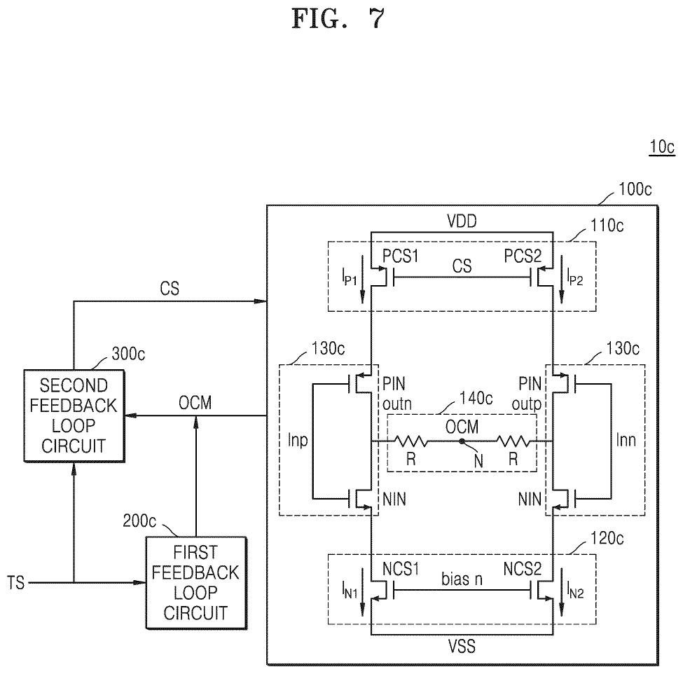

FIG. 7 is a block diagram illustrating a differential amplifier according to an embodiment. A differential amplifier 10c may be an example of the differential amplifier 10 of FIG. 1. A first feedback loop circuit 200c and a second feedback loop circuit 300c may be identical to the first feedback loop circuit 200 and the second feedback loop circuit 300, respectively, of FIG. 1, so that redundant descriptions as those of FIG. 1 are omitted. Briefly, the differential amplifier 10c may differ from the differential amplifier 10a of FIG. 4 in that the positions and transistor types (n-type or p-type) of the first and second current mirrors are swapped.

As shown in FIG. 7, a main amplifier 100c may include a first current mirror 110c, a second current mirror 120c, input transistors 130c, and a common-mode signal sensor 140c. The input transistors 130c and the common-mode signal sensor 140c may be respectively identical to the input transistors 130a and the common-mode signal sensor 140a of FIG. 4, so that redundant descriptions as those of FIG. 4 are omitted.

The first current mirror 110c may generate first currents I_{P1} and I_{P2} and supply the first currents I_{P1} and I_{P2} to the input transistors 130c. The first current mirror 110c may include a plurality of transistors PCS1 and PCS2, and first terminals (e.g., a source terminal) of the plurality of transistors PCS1 and PCS2 may be connected to a voltage terminal VDD. Voltage of the voltage terminal VDD may be higher than voltage of a voltage terminal VSS. Second terminals (e.g., a drain terminal) of the plurality of transistors PCS1 and PCS2 may be connected to the input transistors 130a.

A gate terminal of the transistor PCS1 may be connected to a gate terminal of the transistor PCS2. The gate terminals of the plurality of transistors PCS1 and PCS2 may receive a control signal CS from the second feedback loop circuit 300c. The control signal CS may be a voltage capable of controlling the plurality of transistors PCS1 and PCS2 such that magnitudes of the first currents I_{P1} and I_{P2} are the same as magnitudes of second currents I_{N1} and I_{N2}. Since the first current I_{P2} may be copied from the first current I_{P1} with the same magnitude, the first current mirror 110c may generate the first currents I_{P1} and I_{P2} having the same magnitude as the second currents I_{N1} and I_{N2}. The first current mirror 110c may supply the generated first currents I_{P1} and I_{P2} to the input transistors 130c.

The second feedback loop circuit 300c may control the first current mirror 110c to generate the first currents I_{P1} and I_{P2} having the same magnitude as the second currents I_{N1} and I_{N2}. When the magnitudes of the first currents I_{P1} and I_{P2} are the same as the magnitudes of the second currents I_{N1} and I_{N2}, there is no difference between the first currents I_{P1} and I_{P2} and the second currents I_{N1} and I_{N2} so that the first feedback loop circuit 200c may not need to further consume current by as much as the current difference, thereby decreasing current consumed in the first feedback loop circuit 200c.

The second current mirror 120c may generate the second currents I_{N1} and I_{N2} and allow current flowing through the input transistors 130c to flow to the voltage terminal VSS. The voltage terminal VSS may be connected to a ground terminal.

In some embodiments, the second current mirror 120c may include a plurality of transistors NCS1 and NCS2, and first terminals (e.g., a drain terminal) of the plurality of transistors NCS1 and NCS2 may be connected to the input transistors 130c. The first terminals (e.g., a source terminal) of the plurality of transistors NCS1 and NCS2 may be connected to the voltage terminal VSS.

A gate terminal of the transistor NCS1 may be connected to a gate terminal of the transistor NCS2. The gate terminals of the plurality of transistors NCS1 and NCS2 may receive a bias voltage bias_n. The bias voltage bias_n may refer to a voltage at which the plurality of transistors NCS1 and NCS2 may operate. Since the second current I_{N2} may be copied from the second current I_{N1} with the same magnitude based on the bias voltage bias_n, the second current mirror 120c may generate the second currents I_{N1} and I_{N2} having the same magnitude. The second current mirror 120c may allow the generated second currents I_{N1} and I_{N2} to flow to the voltage terminal VSS.

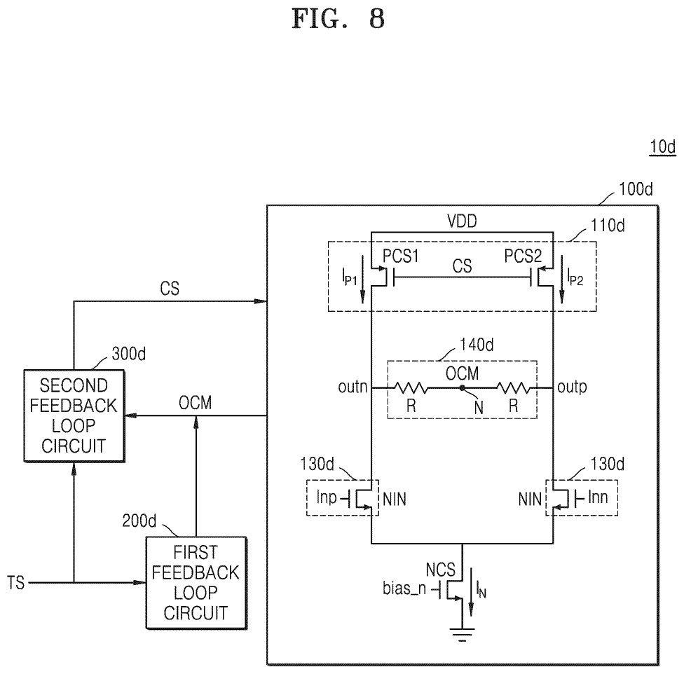

FIG. 8 is a block diagram illustrating a differential amplifier according to an embodiment. A differential amplifier 10d may be an example of the differential amplifier 10 of FIG. 1. A first feedback loop circuit 200d and a second feedback loop circuit 300d may be respectively identical to the first feedback loop circuit 200 and the second feedback loop circuit 300 of FIG. 1, and repeated descriptions as those of FIG. 1 are omitted.

Referring to FIG. 8, a main amplifier 100d may include a first current mirror 110d, a current transistor NCS, input transistors 130d, and a common-mode signal sensor 140d. The common-mode signal sensor 140d may be identical to the common-mode signal sensor 140a of FIG. 4, so that redundant descriptions as those of FIG. 4 are omitted.

The first current mirror 110d may generate first currents I_{P1} and I_{P2} and supply the first currents I_{P1} and I_{P2} to the input transistors 130d. In some embodiments, the first current mirror 110d may include a plurality of transistors PCS1 and PCS2, and first terminals (e.g., a source terminal) of the plurality of transistors PCS1 and PCS2 may be connected to a voltage terminal VDD. Voltage of the voltage terminal VDD may be higher than voltage of a ground terminal. Second terminals (e.g., a drain terminal) of the plurality of transistors PCS1 and PCS2 may be connected to the input transistors 130d.

A gate terminal of the transistor PCS1 may be connected to a gate terminal of the transistor PCS2. The gate terminals of the plurality of transistors PCS1 and PCS2 may receive a control signal CS from the second feedback loop circuit 300d. The control signal CS may be a voltage capable of controlling the plurality of transistors PCS1 and PCS2 such that the sum of magnitudes of the first currents I_{P1} and I_{P2} is the same as the magnitude of second current I_{N}. The second current I_{P2} may be copied from the first current I_{P1} with the same magnitude, and the first current mirror 110d may generate the sum of the first currents I_{P1} and I_{P2} having the same magnitude as the second current I_{N}. The first current mirror 110d may supply the generated first currents I_{P1} and I_{P2} to the input transistors 130d.

The second feedback loop circuit 300d may control the first current mirror 110d to generate the first currents I_{P1} and I_{P2} having the same magnitude as the second current I_{N}. When the sum of the magnitudes of the first currents I_{P1} and I_{P2} are the same as the magnitude of the second current I_{N}, there is no difference between the sum of the first currents I_{P1} and I_{P2} and the second current I_{N}. As a result, the first feedback loop circuit 200d may not need to further consume current by as much as the current difference, thereby decreasing current consumed in the first feedback loop circuit 200d.

The current transistor NCS may generate the second current I_{N} and allow current flowing through the input transistors 130d to flow to the ground terminal. In some embodiments, a first terminal (e.g., a drain terminal) of the current transistor NCS may be connected to the input transistors 130d and a second terminal (e.g., a source terminal) of the current transistor NCS may be connected to the ground terminal. A gate terminal of the current transistor NCS may receive a bias voltage bias_n, which may be a control voltage at which the current transistor NCS may operate. The current transistor NCS may allow the generated second current I_{N} to flow to the ground terminal.

The input transistors 130d may receive at least one pair of differential input signals Inp and Inn and generate at least one pair of differential output signals outn and outp by amplifying the at least one pair of differential input signals. In some embodiments, the input transistors 130d may include one P-type transistor PIN and one N-type transistor NIN.

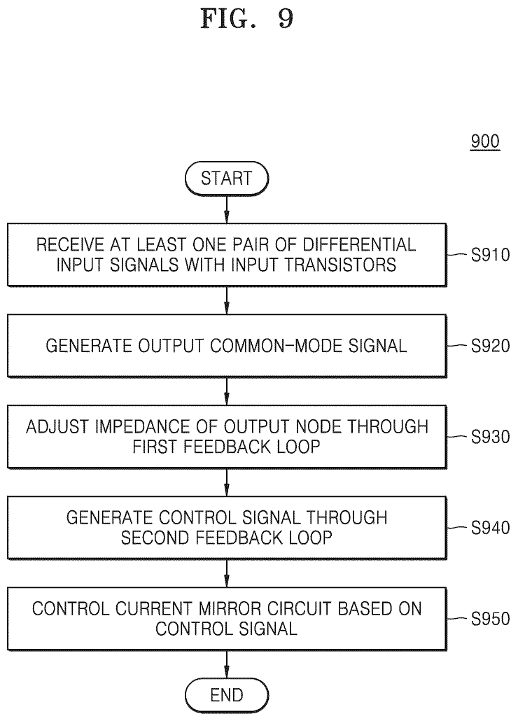

FIG. 9 is a flowchart illustrating an operating method of a differential amplifier according to an embodiment. As illustrated in FIG. 9, an operating method 900 of a differential amplifier may include a plurality of operations S910 to S950.

Referring to FIGS. 4 and 9, in operation S910, the input transistors 130a may receive at least one pair of differential input signals. In some embodiments, the input transistors 130a connected to the first current mirror 110a and the second current mirror 120a may receive one pair of differential input signals Inp and Inn.

In operation S920, the output common-mode signal OCM may be generated. In some embodiments, the main amplifier 100a may generate one pair of differential output signals outn and outp by amplifying the one pair of differential input signals Inp and Inn and generate the output common-mode signal OCM based on the one pair of differential output signals outn and outp. The main amplifier 100a may output the output common-mode signal OCM at the output node N.

In operation S930, impedance of the output node may be adjusted through the first feedback loop. In some embodiments, the first feedback loop circuit 200a may generate the output common-mode signal OCM, based on the output common-mode signal OCM and a target signal TS. The first feedback loop may refer to a path starting from and returning back to the output node N via the first feedback loop circuit 200. The target signal TS may refer to a predetermined signal for controlling the output common-mode signal OCM.

The first feedback loop circuit 200a has a relatively low output impedance and is connected to the output node N, and may thus decrease the impedance of the output node N. When the impedance of the output node N decreases, phase margin of the differential amplifier 10a may increase. As the phase margin of the differential amplifier 10a increases, the stability of the differential amplifier 10a may further improve. The differential amplifier 10a may increase the stability of the differential amplifier 10a by forming the first feedback loop.

In operation S940, the control signal may be generated through a second feedback loop. In some embodiments, the second feedback loop circuit 300a may form the second feedback loop and generate the control signal based on the output common-mode signal OCM and the target signal TS. The second feedback loop may refer to a path from the output node N through the second feedback loop circuit 300a to the gate terminals of a plurality of transistors NCS1 and NCS2. For example, the second feedback loop circuit 300a may receive the output common-mode signal OCM and the target signal TS through a plurality of input terminals and generate the control signal CS by comparing the received output common-mode signal OCM with the received target signal TS.

In operation S950, a current mirror may be controlled based on the control signal. In some embodiments, the first current mirror 110a may include the plurality of transistors NCS1 and NCS2 and receive the control signal CS through the gate terminals of the plurality of transistors NCS1 and NCS2. Based on the received control signal CS, magnitudes of the first currents I_{N1} and I_{N2} may be generated to be the same as magnitudes of the second currents I_{P1} and I_{P2}.

The second feedback loop circuit 300a may control the first current mirror 110a to generate the first currents I_{N1} and I_{N2} having the same magnitude as the second currents I_{P1} and I_{P2}. When the magnitudes of the first currents I_{N1} and I_{N2} are the same as the magnitudes of the second currents I_{P1} and I_{P2}, there is no difference between the first currents I_{N1} and I_{N2} and the second currents I_{P1} and I_{P2} so that the first feedback loop circuit 200a may not need to further consume current by as much as the current difference, thereby decreasing current consumed in the first feedback loop circuit 200a.

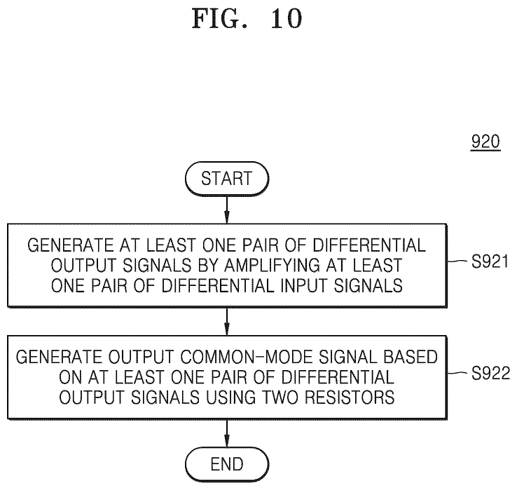

FIG. 10 is a flowchart illustrating an operating method of a differential amplifier circuit, according to an embodiment. As illustrated in FIG. 10, an operating method 920 of the differential amplifier may include a plurality of operations S921 and S922. The operating method 920 of the differential amplifier may be an embodiment of operation S920 of the operating method 900 of the differential amplifier of FIG. 9.

Referring to FIGS. 4 and 10, in operation S921, at least one pair of differential output signals may be generated by amplifying at least one pair of differential input signals. In some embodiments, the input transistors 130a may receive the at least one pair of differential input signals Inp and Inn and generate the at least one pair of differential output signals outn and outp by amplifying the at least one pair of differential input signals. For example, the input transistors 130a may include P-type transistors PIN and N-type transistors NIN and may include two inverters. Each of the inverters may include one P-type transistor PIN and one N-type transistor NIN and may include a circuit receiving an input signal and outputting an output signal by inverting the input signal.

In operation S922, using two resistors, an output common-mode signal may be generated based on the at least one pair of differential output signals. In some embodiments, the common-mode signal sensor 140a may generate the output common-mode signal OCM based on the at least one pair of differential output signals outn and outp and output the output common-mode signal OCM at the output node N. The common-mode signal sensor 140a may include two resistors R, and the output node N may be located between the two resistors R. The two resistors R may divide the at least one pair of differential output signals outn and outp and generate the output common-mode signal OCM.

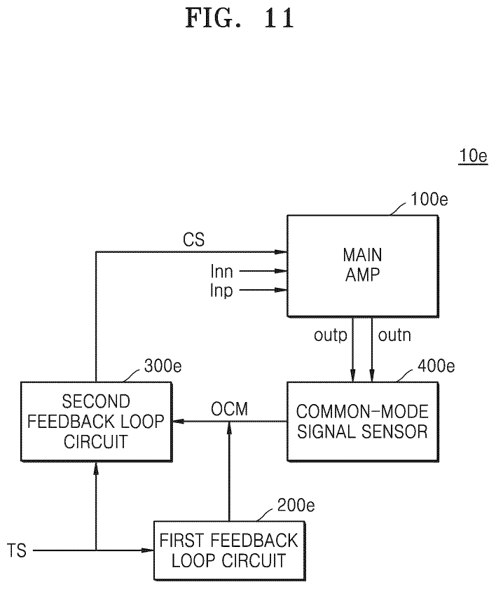

FIG. 11 is a block diagram illustrating a differential amplifier according to an embodiment. A differential amplifier 10e may be an example of the differential amplifier 10 of FIG. 1. A first feedback loop 200e and a second feedback loop circuit 300e may be respectively identical to the first feedback loop circuit 200 and the second feedback loop circuit 300 of FIG. 1, and repeated descriptions as those of FIG. 1 are omitted.

A main amplifier 100e may receive at least one pair of differential input signals Inp and Inn and generate at least one pair of differential output signals outn and outp by amplifying the at least one pair of differential input signals. In some embodiments, the main amplifier 100e may include input transistors (not shown). The input transistors may include P-type transistors and N-type transistors and may form two inverters. Each of the inverters may include one P-type transistor and one N-type transistor and may be a circuit receiving an input signal and outputting an output signal by inverting the input signal.

In some embodiments, the main amplifier 100e may further include a current mirror (not shown), which may be the same as one of the first current mirror circuits 110a, 110c, and 110d of FIGS. 4, 7, and 8.

A common-mode signal sensor 400e may generate an output common-mode signal OCM based on the at least one pair of differential output signals outn and outp and output the output common-mode signal OCM at an output node (not shown). The common-mode signal sensor 140a may include two resistors R, and the output node may be located between the two resistors R. The two resistors R may divide the at least one pair of differential output signals outn and outp and generate the output common-mode signal OCM.

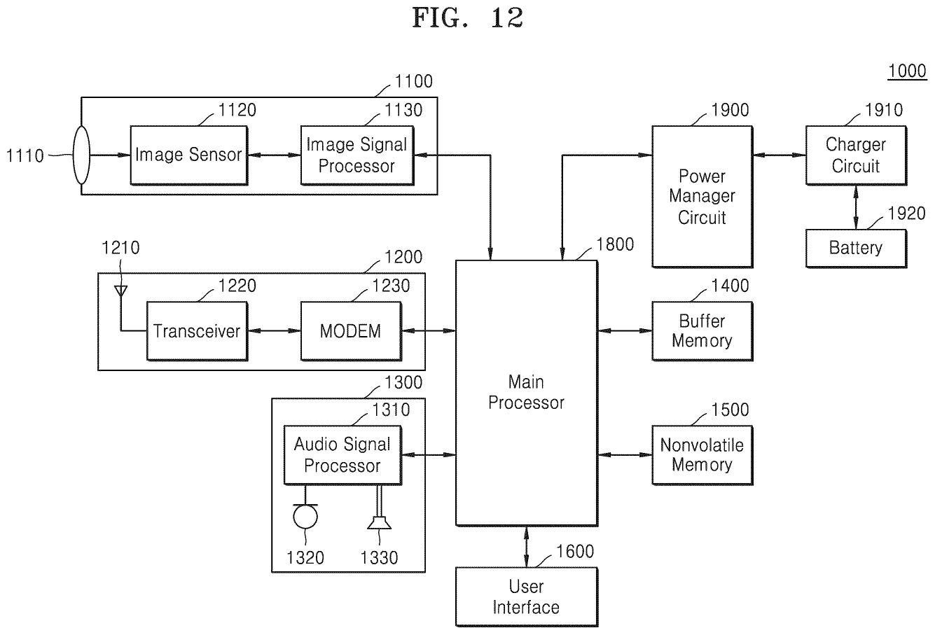

FIG. 12 is a block diagram illustrating an electronic device according to an embodiment.

Referring to FIG. 12, an electronic device 1000 may include various electronic circuits. As an example, the electronic circuits in the electronic device 1000 may include an image processing block 1100, a communication block 1200, an audio processing block 1300, a buffer memory 1400, a nonvolatile memory 1500, a user interface 1600, a main processor 1800, a power manager circuit 1900, and a charger integrated circuit 1910.

The electronic device 1000 may be connected to a battery 1920, and the battery 1920 may supply power used in operating the electronic device 1000. However, the embodiment is not limited thereto, and the power supplied to the electronic device 1000 may be provided by an internal/external power source other than the battery 1920.

The image processing block 1100 may receive light through a lens 1110. An image sensor 1120 and an image signal processor 1130 included in the image processing block 1100 may generate image information related to external objects based on the received light.

The communication block 1200 may exchange signals with external devices/systems through an antenna 1210. According to at least one of various wired/wireless communication protocols, a transceiver 1220 and a modulator/demodulator (MODEM) 1230 of the communication block 1200 may process the signals exchanged with the external devices/systems.

The audio processing block 1300 may process sound information using an audio signal processor 1310. The audio processing block 1300 may receive audio inputs through a microphone 1320 and output audio sound through a speaker 1330.

The buffer memory 1400 may store data used in operating the electronic device 1000. As an example, the buffer memory 1400 may temporarily store processed data or data to be processed by the main processor 1800. As an example, the buffer memory 1400 may include a volatile memory such as static random access memory (SRAM), dynamic random access memory (DRAM), and synchronous dynamic random access memory (SDRAM), and/or a nonvolatile memory such as phase-change random access memory (PRAM), magneto-resistive random access memory (MRAM), resistive random access memory (ReRAM), and ferro-electric random access memory (FRAM).

The nonvolatile memory 1500 may store data regardless of whether power is supplied to the electronic device 1000. As an example, the nonvolatile memory 1500 may include at least one of various nonvolatile memories such as a flash memory, PRAM, MRAM, ReRAM, and FRAM. As an example, the nonvolatile memory 1500 may include a removable memory such as a secure digital card or solid state drive, and/or an embedded memory such as an embedded multimedia card (eMMC).

The user interface 1600 may mediate communication between a user and the electronic device 1000. As an example, the user interface 1600 may include an input interface for receiving inputs from a user and an output interface for providing information for the user.

The main processor 1800 may control all operations of components of the electronic device 1000. The main processor 1800 may process a variety of operations for operating the electronic device 1000. As an example, the main processor 1800 may be implemented as a general-purpose processor, special-purpose processor, application processor, microprocessor, etc., and include one or more processor cores.

The power manager circuit 1900 may supply power to the components of the electronic device 1000 and manage the power. For example, the power manager circuit 1900 may output system voltage based on power provided from the charger integrated circuit 1910 and/or the battery 1920. Depending on temperature, operation modes (such as a performance mode, standby mode, sleep mode), etc., of the components, the power manager circuit 1900 may adjust the frequency of respective components, voltage level of the provided system voltage, and the like.

Based on power provided from an external power source, the charger integrated circuit 1910 may charge the battery 1920 or provide power for the power manager circuit 1900. Alternatively, based on power provided from the battery 1920, the charger integrated circuit 1910 may provide power through a wired or wireless power interface to an external device.

The electronic device 1000 may include the differential amplifier (not shown) described with reference to FIGS. 1 to 11. The differential amplifier may form two feedback loops and thus may increase its stability and decrease its current consumption. In other words, the differential amplifier may have a first feedback loop circuit (e.g., 200 of FIG. 1) and thus may decrease impedance of an output node of a main amplifier (e.g., 100 of FIG. 1) and increase phase margin of the differential amplifier, thereby increasing the stability of the differential amplifier. The differential amplifier may include a second feedback loop (for example, 300 of FIG. 1) and thus may control current generated by a first current mirror (for example, 110 of FIG. 1) and decrease current consumed in the first feedback loop (for example, 200 of FIG. 1).

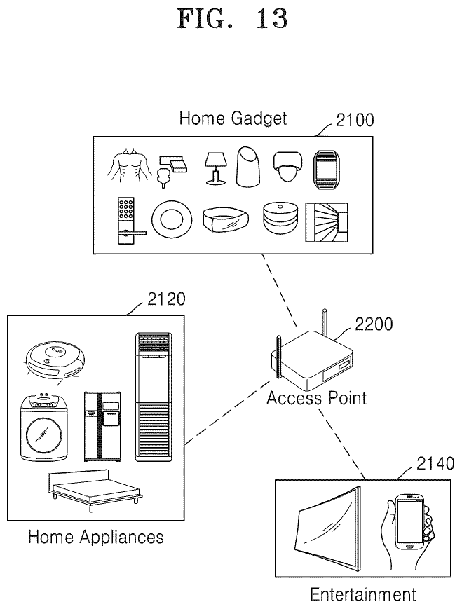

FIG. 13 is a block diagram illustrating communication apparatuses including a communication device according to an embodiment.

Referring to FIG. 13, a home gadget 2100, a home appliance 2120, an entertainment device 2140, and an access point (AP) 2200 may include a differential amplifier (not shown) according to embodiments described above (e.g., differential amplifier 10 or 10a-10d described above). As such, the differential amplifier may form two feedback loops (e.g., 200 and 300) and thus may exhibit improved stability and reduced current consumption as compared to related art amplifiers. As described earlier, the improved stability may be a result of lower impedance of an output node of a main amplifier (e.g., 100 of FIG. 1) and increased phase margin of the differential amplifier. The second feedback loop may control current generated by a first current mirror (for example, 110 of FIG. 1) and decrease current consumed in the first feedback loop (for example, 200 of FIG. 1).

In some embodiments, the home gadget 2100, the home appliance 2120, the entertainment device 2140, and the AP 2200 may form an internet of things (IoT) network system. The communication apparatuses shown in FIG. 13 are only examples, and it will be understood that other communication apparatuses may include an embodiment of a differential amplifier as described above.

In the home gadget 2100, the home appliance 2120, the entertainment device 2140, and the AP 2200, a voltage signal may be amplified by the differential amplifier. In some embodiments, the home gadget 2100, the home appliance 2120, the entertainment device 2140, and the AP 2200 may include the above-described feedback loops, whereby and stabilities of the home gadget 2100, the home appliance 2120, the entertainment device 2140, and the AP 2200 may be improved.

While the inventive concept has been particularly shown and described with reference to embodiments thereof, it will be understood that various changes in form and details may be made therein without departing from the spirit and scope of the following claims.

What is claimed is:

1. A differential amplifier comprising:
a main amplifier configured to generate at least one pair of differential output signals by amplifying at least one pair of differential input signals, and to generate an output common-mode signal based on the at least one pair of differential output signals, the main amplifier including a first current mirror that generates first currents;
a first feedback loop circuit, connected to an output node of the main amplifier which outputs the output common-mode signal, and configured to form a first feedback loop that feeds back the output common-mode signal; and
a second feedback loop circuit configured to generate a control signal controlling the first currents based on the output common-mode signal, and form a second feedback loop.

2. The differential amplifier circuit of claim 1, wherein the first feedback loop circuit includes a first operational amplifier configured to receive a target signal and the output common-mode signal as input signals and output the output common-mode signal as an output signal.

3. The differential amplifier circuit of claim 1, wherein the second feedback loop circuit includes a second operational amplifier configured to compare a target signal with the output common-mode signal and output the control signal based on the comparison.

4. The differential amplifier circuit of claim 3, wherein the second operational amplifier has a gain of 1.

5. The differential amplifier circuit of claim 1, wherein the main amplifier circuit further includes:
input transistors configured to generate the at least one pair of differential output signals by amplifying the at least one pair of differential input signals; and
a second current mirror circuit configured to supply second currents to the input transistors, and
the control signal controls the first current mirror circuit such that each of the first currents is equal to each of the second currents.

6. The differential amplifier circuit of claim 5, wherein:
the first current mirror circuit includes two N-type transistors,
the second current mirror circuit includes two P-type transistors, and
the second feedback loop circuit provides the control signal to gate terminals of the two N-type transistors.

7. The differential amplifier circuit of claim 5, wherein:
the first current mirror circuit includes two P-type transistors,
the second current mirror circuit includes two N-type transistors, and
the second feedback loop circuit provides the control signal to gate terminals of the two P-type transistors.

8. The differential amplifier circuit of claim 1, wherein:
the main amplifier circuit further includes input transistors configured to generate the at least one pair of differential output signals by amplifying the at least one pair of differential input signals;
the first current mirror circuit includes two P-type transistors, and
the second feedback loop circuit provides the control signal to gate terminals of the two P-type transistors.

9. The differential amplifier circuit of claim 1, wherein:
the main amplifier circuit further includes a common-mode signal sensor configured to generate the output common-mode signal based on the at least one pair of differential output signals.

10. The differential amplifier circuit of claim 9, wherein:
the common-mode signal sensor includes a first resistor and a second resistor, and
the output node is located between the first resistor and the second resistor.

11. An electronic device comprising:
a main amplifier configured generate at least one pair of differential output signals by amplifying at least one pair of differential input signals, the main amplifier including a first current mirror that includes a plurality of transistors;
a common-mode signal sensor configured to provide an output common-mode signal based on the at least one pair of differential output signals;
a first feedback loop circuit connected to an output node of the common-mode signal sensor which outputs the output common-mode signal, and configured to provide a feedback loop for the output common-mode signal; and
a second feedback loop circuit configured to generate a control signal controlling the first current mirror based on the output common-mode signal and to provide the control signal to gate terminals of the plurality of transistors.

12. The electronic device of claim 11, wherein the first feedback loop circuit includes a first operational amplifier configured to receive a target signal and the output common-mode signal as input signals and output the output common-mode signal as an output signal.

13. The electronic device of claim 11, wherein the second feedback loop circuit includes a second operational amplifier configured to compare a target signal with the output common-mode signal and output the control signal based on the comparison.

14. The electronic device of claim 11, wherein the main amplifier circuit further includes:
input transistors configured to generate the at least one pair of differential output signals by amplifying the at least one pair of differential input signals; and
a second current mirror circuit configured to supply second currents to the input transistors, and
the control signal controls the first current mirror circuit such that the first currents are equal to the second currents.

15. The electronic device of claim 11, wherein the main amplifier circuit further includes input transistors configured to generate the at least one pair of differential output signals by amplifying the at least one pair of differential input signals;
the first current mirror circuit includes two P-type transistors, and
the second feedback loop circuit provides the control signal to gate terminals of the two P-type transistors.

16. The electronic device of claim 11, wherein:
the common-mode signal sensor includes a first resistor and a second resistor, and
the output node is located between the first resistor and the second resistor.

17. An operating method of a differential amplifier, the method comprising:
receiving at least one pair of differential input signals through input transistors connected to terminals of one or more current mirrors;
generating an output common-mode signal based on the at least one pair of differential input signals;
controlling impedance of an output node at which the output common-mode signal is provided, based on the output common-mode signal and a target signal through a first feedback loop;
generating a control signal based on the output common-mode signal and the target signal through a second feedback loop; and
controlling the one or more current mirrors based on the control signal.

18. The operating method of the differential amplifier circuit of claim 17, wherein the generating of the control signal includes comparing the output common-mode signal with the target signal and generating the control signal.

19. The operating method of the differential amplifier circuit of claim 17, wherein the differential amplifier circuit includes:
a first current mirror circuit generating first currents; and
a second current mirror circuit generating second currents, and
the controlling of the current mirror circuits based on the control signal includes controlling the first current mirror circuit based on the control signal such that the first currents are equal to the second currents.

20. The operating method of the differential amplifier circuit of claim 17, wherein the generating of the output common-mode signal includes:
generating at least one pair of differential output signals by amplifying at least one pair of differential input signals; and
generating the output common-mode signal based on the at least one pair of differential output signals, using two resistors.
